(19) United States
(12) Patent Application Publication
(10) Pub. No.: US 2025/0104976 A1
(43) Pub. Date: Mar. 27, 2025

(54) RECOMBINATION CHANNELS FOR ANGLE CONTROL OF NEUTRAL REACTIVE SPECIES

(71) Applicant: Applied Materials, Inc., Santa Clara, CA (US)

(72) Inventor: Glen F. R. Gilchrist, Danvers, MA (US)

(73) Assignee: Applied Materials, Inc., Santa Clara, CA (US)

(21) Appl. No.: 18/975,419

(22) Filed: Dec. 10, 2024

Related U.S. Application Data
(62) Division of application No. 17/744,000, filed on May 13, 2022.

(51) Int. Cl. H01J 37/32

(52) U.S. Cl. CPC H01J 37/32422; H01J 37/32357; H01J 2237/026; H01J 2237/3341

(57) ABSTRACT

Provided herein are approaches for angle control of neutral reactive species ion beams. In one approach, a workpiece processing apparatus may include a plasma source operable to generate a plasma within a plasma chamber enclosed by a chamber housing, and an extraction plate coupled to the chamber housing. The extraction plate may include a recombination array having a plurality of channels operable to direct one or more radical beams to a workpiece at a non-zero angle relative to a perpendicular extending from a main surface of the workpiece.

### CROSS-REFERENCE TO RELATED APPLICATION

This application is a divisional application of pending U.S. non-provisional application Ser. No. 17/744,000, filed May 13, 2022, the entire contents of which application is incorporated by reference herein.

### FIELD OF THE DISCLOSURE

The disclosure relates generally to angle control for neutral reactive species ion beams, and more particularly, to an extraction plate including a plurality of recombination channels for use in directed reactive ion etch processes.

### BACKGROUND OF THE DISCLOSURE

Fabrication of advanced three-dimensional semiconductor structures with complex surface topology and high packing density presents many technical challenges. Patterning using extreme ultraviolet lithography (EUVL) typically results in printed features that do not match the designed features. For example, trenches or vias are typically shorter than desired, and the tip-to-tip distance is larger than desired, which results in incomplete overlap with vias or contact holes in layers above and below. This in turn often results in high contact resistance or open circuit and device failure. EUVL double patterning is one current approach used to correct this problem, but EUVL tools are expensive and slow (e.g., as low as 1 hour per wafer per track), such that lithography is typically a bottle neck in wafer process flow.

Another problem encountered in EUVL patterning are bridge defects resulting from incomplete development of the EUV photoresist. Pattern correction and elimination of bridge defects in the EUV photoresist may be accomplished using an angled beam of reactive neutral species like oxygen radicals. However, precise angle control of reactive neutrals, generated in a plasma, is difficult to achieve. For example, reactive neutrals are not controllable using electrical fields. Therefore, while the angle of the charged ion beam may be more easily controlled, the same is not true for reactive neutrals. As the angles used for DRIE decrease (i.e., become closer to perpendicular to the workpiece), the lack of angular control of the reactive neutrals becomes more pronounced. Reactive neutrals are defined as those radicals/atoms which are highly reactive with some of the materials on the workpiece, but not others. For example, under the correct process conditions, chlorine has a high reaction rate with TiN, but a very low reaction rate with SiO₂. These reactive neutrals serve to etch portions of the workpiece, without affecting other parts. The inability to control the angle at which the reactive neutrals are directed toward the workpiece may compromise the speed and/or precision of the etching process. In certain examples, the inability to control the angle at which the reactive neutrals are directed toward the workpiece may make it difficult to achieve the specified feature on the workpiece.

Therefore, it would be beneficial to control the angle and angular distribution (emittance) at which reactive neutrals are directed toward a workpiece. It is with respect to this and other considerations, the present disclosure is provided.

### SUMMARY

This Summary is provided to introduce a selection of concepts in a simplified form further described below in the Detailed Description. This Summary is not intended to identify key features or essential features of the claimed subject matter, nor is the summary intended as an aid in determining the scope of the claimed subject matter.

In one embodiment, a workpiece processing apparatus may include a plasma source operable to generate a plasma within a plasma chamber enclosed by a chamber housing, and an extraction plate coupled to the chamber housing. The extraction plate may include a recombination array having a plurality of channels operable to direct one or more radical beams to a workpiece at a non-zero angle relative to a perpendicular extending from a main surface of the workpiece.

In another embodiment, an extraction plate assembly coupled to a chamber housing of a plasma generator may include a main body oriented at a non-zero angle relative to a perpendicular extending from a main surface of the workpiece, and a plurality of channels extending through the main body, the plurality of channels operable to deliver one or more radical beams to the workpiece at the non-zero angle.

In yet another embodiment, a method of controlling neutral reactive species ion beams may include generating a plasma within a plasma chamber of a plasma source, and directing, through an extraction plate coupled to the source, one or more radical beams to a workpiece at a non-zero angle relative to a perpendicular extending from a main surface of the workpiece. The extraction plate may include a recombination array including a plurality of channels for controlling the non-zero angle and an angular spread of the one or more radical beams to the workpiece.

### BRIEF DESCRIPTION OF THE DRAWINGS

By way of example, embodiments of the disclosure will now be described, with reference to the accompanying drawings, in which:

FIG. 1 is a schematic diagram of a system according to embodiments of the present disclosure;

FIG. 2A demonstrates an extraction plate according to embodiments of the present disclosure;

FIG. 2B demonstrates an example channel of the extraction plate of FIG. 2A according to embodiments of the present disclosure;

FIGS. 3A-3B are graphs illustrating plots of ln(γ) versus 1/T for the heterogeneous recombination of oxygen atoms on quartz, under different conditions, according to embodiments of the present disclosure;

FIGS. 4A-4B are graphs illustrating increases in γ with increases in temperature for Ti—SiOx and stainless steel, according to embodiments of the present disclosure;

FIG. 5 is a graph illustrating a probability for a radical to be transmitted through a 20 mm×2 mm cylindrical channel as a function of initial elevation angle and γ, according to embodiments of the present disclosure;

FIGS. 6A-6B depict an example reactive ion etch process using the plurality of recombination channels, according to embodiments of the present disclosure; and

FIG. 7 is a flowchart depicting a method according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

A plasma source including a heated extraction plate and methods in accordance with the present disclosure will now be described more fully hereinafter with reference to the accompanying drawings, where embodiments of the disclosure are shown. The plasma source and methods of the disclosure may be described in many different forms and are not to be construed as being limited to the embodiments set forth herein. Instead, these embodiments are provided so this disclosure will be thorough and complete, and will fully convey the scope of the system and method to those skilled in the art.

In view of the foregoing deficiencies identified with the prior art, provided herein are approaches for generating a beam of neutral species including, but not limited to, reactive neutral species like O, H, F, Cl, etc., directed toward a workpiece at a specified angle and angular distribution. Embodiments herein achieve neutral species angle control using specially shaped channels of an extraction plate, the channels operable to reflect those species having trajectories outside of a specified angle range. In some embodiments, the extraction plate is heated to act as a low-pass filters for neutral species, including reactive radicals like oxygen atoms. These channels, when tilted with respect to the workpiece, such as a semiconductor 3D integrated circuit, provide a directional, angled neutral beam with low emittance. In one non-limiting application, the extraction plate may correct patterning defects of trenches in a EUV photoresist, such as bridge defects or incomplete trenches, using oxygen atoms directed parallel to the long axis of the trenches to elongate the trenches, reduce the bridge tip-to-tip distance, and thus provide better contact with lower contact resistance to layers above and below the EUV photoresist.

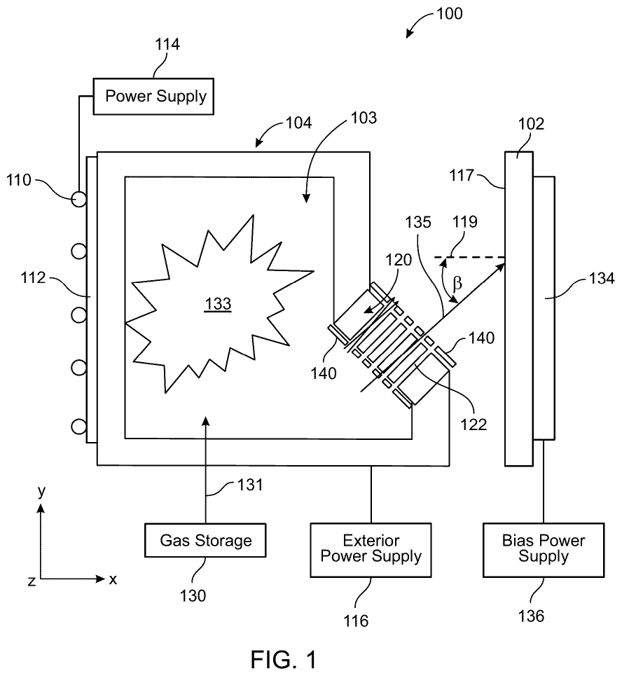

FIG. 1 shows a first embodiment of a workpiece processing apparatus 100 for controlling the angle at which ions and reactive neutrals are directed toward a workpiece 102. The workpiece processing apparatus 100 may include a plasma chamber 103 of a plasma source 104, the plasma chamber 103 being defined by a chamber housing 106. In some embodiments, an antenna 110 is disposed external to the plasma chamber 103, proximate a dielectric window 112. The dielectric window 112 may also form one of the walls that define the plasma chamber 103. The antenna 110 may be electrically connected to a power supply 114 (e.g., RF power supply), which supplies an alternating voltage to the antenna 110. Although non-limiting, the voltage may be at a frequency of, for example, 2 MHz or more. While the dielectric window 112 and antenna 110 are shown on one side of the plasma chamber 103, other embodiments are also possible. The chamber housing 106 may be made of a conductive material, such as graphite, and may be biased at an extraction voltage, such as by extraction power supply 116. The extraction voltage may be, for example, 1 kV, when patterning a dielectric (e.g., SiO2, SiON, SiN, etc) or metal layer. When an EUV resist layer is being patterned, however, bias voltage may not be required because it is a carbon-polymer and highly reactive to neutral oxygen radicals.

The workpiece processing apparatus 100 may further include an extraction plate 120 having a plurality of channels 122. The extraction plate 120 may form a portion of the chamber housing 106 defining the plasma chamber 103. Although non-limiting, the extraction plate 120 may be disposed on an opposite side of the plasma chamber 103 from the dielectric window 112. In certain embodiments, the extraction plate 120 may be constructed from an insulating material, such as quartz, sapphire, alumina or a similar insulating material. The use of an insulating material may allow recombination of radicals to form molecules, as will be described in greater detail herein. In other embodiments, the extraction plate 120 may be constructed of a conducting material.

As shown, the workpiece 102 may be disposed proximate the extraction plate 120, outside the plasma chamber 103. In some embodiments, the extraction plate 120 may be oriented at a non-zero angle ‘B’ (e.g., between approximately 20° and) 80° relative to a perpendicular 119 extending from the workpiece 102. One or more radiation shields 140 may be provided adjacent the extraction plate 120. As will be described in greater detail herein, the orientation of the extraction plate 120 and the plurality of channels 122 causes one or more radical beams 135 to impact the workpiece 102 at the non-zero angle (or within an acceptable +/− deviation amount from the non-zero angle). Throughout this disclosure, extraction angles are referenced to the perpendicular 119, which extends normal to a plane defined by a main surface 117 of the workpiece 102. Thus, an extraction angle of 0° refers to a path that is perpendicular to the main surface 117 of the workpiece 102, while an extraction angle of 90° is a path parallel to the main surface 117 of the workpiece 102. Emittance, or angular distribution, of the radical beams, refers to beam spread in two axes, x and y, orthogonal to the axes of propagation of the radical beam 135. In some embodiments, the channels 122 are cylindrical holes, and the beam spread is controlled in two axes to provide high angle for tip-to-tip push and low beam spread to limit line CD loss in the axis perpendicular to the tip-to-tip push direction.

In operation, the antenna 110 may be powered using a RF signal from the power supply 114 so as to inductively couple energy into the plasma chamber 103. This inductively coupled energy excites the feed gas introduced from a gas storage container 130 via a gas inlet 131, thus generating a plasma 133. While FIG. 1 shows antenna 110, it will be appreciated that other plasma generators may also be used with the present disclosure. For example, a capacitively coupled plasma generator may be used in other embodiments.

The plasma 133 within the plasma chamber 103 may be biased at the voltage being applied to the chamber housing 106 by the extraction power supply 116. The workpiece 102, which may be disposed on a platen 134, may be electrically biased by a bias power supply 136. The difference in potential between the plasma 133 and the workpiece 102 causes ions in the plasma 133 to be accelerated through the extraction plate 120 in the form of one or more ribbon ion beams and toward the workpiece 102. In other words, positive ions are attracted toward the workpiece 102 when the voltage applied by the extraction power supply 116 is more positive than the bias voltage applied by the bias power supply 136. Thus, to extract positive ions, the chamber housing 106 may be biased at a positive voltage, while the workpiece 102 is biased at a less positive voltage, ground or a negative voltage. In other embodiments, the chamber housing 106 may be grounded, while the workpiece 102 is biased at a negative voltage. In yet other embodiments, the chamber housing 106 may be biased at a negative voltage, while the workpiece 102 is biased at a more negative voltage. In yet another embodiment both the chamber housing 106 and the workpiece 102 may be grounded and ions generated in the plasma 133 will have only thermal velocity, typically less than 1 eV.

In some embodiments, the extraction plate 120 may have a separate power supply (not shown) for increasing a temperature of the extraction plate 120 relative to the chamber housing 106 and/or the interior of the plasma chamber 103. As will be described in greater detail herein, increasing the temperature of the extraction plate 120 causes heated channels 122 to function as low-pass filters for neutral species, including reactive radicals like oxygen atoms. These channels 122, when heated and tilted with respect to workpiece 102, provide a directional, angled neutral radical beam 135 with low emittance in two axes, x and y, orthogonal to the axes of propagation of the radical beam to specifically target features to be etched.

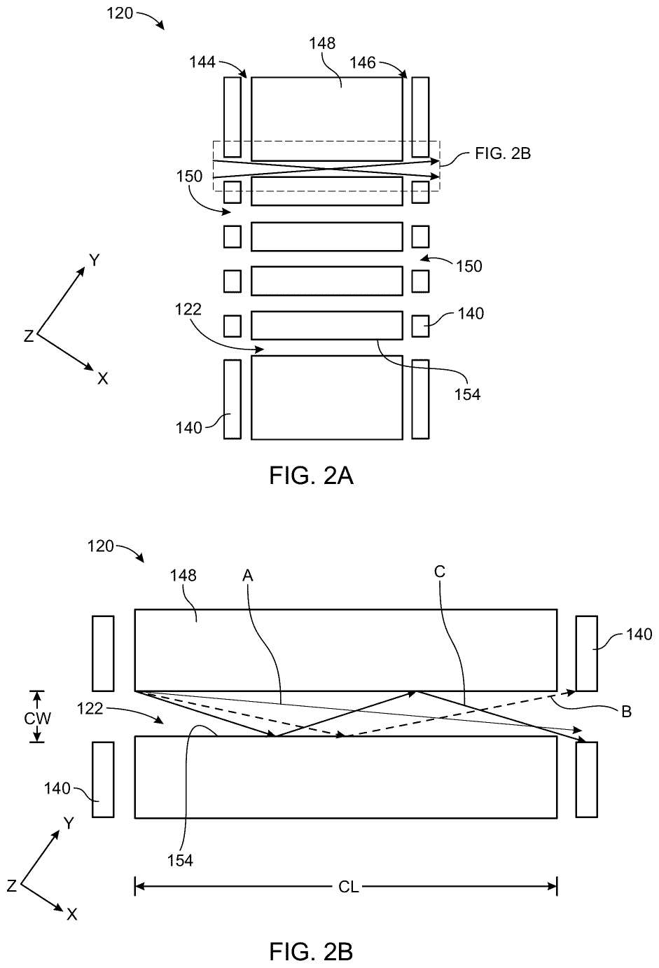

Turning now to FIGS. 2A-2B, the extraction plate 120 according to embodiments of the present disclosure will be describe in greater detail. The extraction plate 120 may be a heated recombination array including the plurality of channels 122 extending between a first side 144 and a second side 146 of a main body 148. The first side 144 of the main body 148 may be disposed within the plasma chamber 103 (FIG. 1), while the second side 146 may be disposed outside the plasma chamber 103. A first radiation shield 140 may be positioned proximate the first side 144 and a second shield may be positioned proximate the second side 146. As shown, each of the radiation shields 140 may include openings 150, which are sized and generally aligned with each channel 122. The radiation shields 140 serve to limit radiative heat transfer from the recombination array to the workpiece 102 and the rest of the process chamber and from the plasma source 104 to the recombination array, and may be cooled, heated or passive, and may be easily removed during a PM cycle. In some embodiments no radiation shields 140 are present.

The channels 122 are used to direct reactive neutrals toward the workpiece 102 at a predetermined angle. In some examples, plasma sheath modulation and electric fields may be used to control the angle at which the ions exit the channels 122 along the second side 146. However, reactive neutrals are not affected by either of these mechanisms and therefore tend to leave the extraction channels 122 in a random manner. The reactive neutrals travel in straight lines until they collide with other particles or structures. For example, the reactive neutrals may collide with an inner sidewall or surface 154 of the channels 122 and/or with other ions, atoms, molecules or reactive neutrals. Collisions between reactive neutrals including radicals and atoms and a surface may result in recombination to form molecules which are typically much less reactive and will not affect the workpiece 102. Providing the channels 122 through the extraction plate 120 provides angular control for the reactive neutrals.

As best shown in FIG. 2B, each channel 122 has a length (‘CL’) and a diameter (CD), wherein the length is at least five times greater than the diameter, preferably ten times greater. Having a neutral species channel 122 with a high aspect ratio will have a narrower distribution of extraction angles than a neutral species channel with a lower aspect ratio. Furthermore, the orientation or tilt of the neutral species channels 122 may determine the central extraction angle, while the aspect ratio of the neutral species channels 122 may determine the distribution of the extraction angles.

In this non-limiting embodiment, the ratio may be 10:1, for example, with radical trajectories represented by arrows A-C. Radicals will travel in straight lines with their thermal velocity (e.g., 400-2000 m/s) until they collide with a molecule, atom, radical or surface. Single atom radicals like H, N, O, F and Cl, atoms like He, Ne and Ar, and small molecules like H2, N2 and O2, have elastic collisions with each other and specular reflection (angle of incidence, θi equals angle of reflection θr) upon collision with surfaces. For example, a radical may have zero, one or multiple collisions with the inner surface 154 of the channel 122, depending on its entry position and elevation angle (i.e., angle with respect to the long axis of the channel 122). Arrow ‘A’ represents the trajectory vector of a radical that enters at the top of the channel 122 (in the orientation shown) and has an elevation angle of −5°. Since the channel 122 has an aspect ratio of 10:1, any radical entering at the top of the channel 122 and having elevation angle less than arctan(1/10) or 5.7° will traverse the channel 122 without hitting the inner surface 154. Arrow ‘B’ is a vector having an elevation angle of 11° so it has one wall collision, and arrow ‘C’ is a vector having an elevation angle of 16° so it has two wall collisions.

Heterogeneous recombination of radicals to form molecules occurs on solid surfaces, such as the inner surface 154 of the channel 122, and the recombination probability, γ, typically increases with increased temperature. Equations (1) to (3) below, show the heterogeneous recombination of oxygen radicals, on a quartz surface, to form an oxygen molecule.

$$2 O ( g ) + quartz -> 2 O ( a ) \qquad ( 1 )$$

$$2 O ( a ) -> O 2 ( a ) \qquad ( 2 )$$

$$O 2 ( a ) -> O 2 ( g ) \qquad ( 3 )$$

wherein the overall reaction is as follows:

$$2 O ( g ) + quartz -> O 2 ( g ) + quartz \qquad ( 4 )$$

For equations (1) to (3), the overall reaction is given by equation (4) where the quartz surface is not altered by the reaction but is essential as a catalyst. Reaction rate is a function of the concentration of the reactants and the rate constant, k, and the overall reaction rate is dominated by the rate of the slowest (rate limiting) step. The rate of formation of O2(g), through reactions 1-4, may be written as¹⁻³:

$$d [ O 2 ( g ) ] d t = {k [ O ( g ) ]}^{2} \qquad ( 5 )$$

It has been shown that the rate constant is an exponential function of temperature and activation energy, Ea as:

$$k = A e - E a R T \qquad ( 6 )$$

where A is a pre-exponential factor, R is the universal gas constant, and T is the absolute temperature. A plot of ln(k) versus 1/T has slope equal to −Ea.

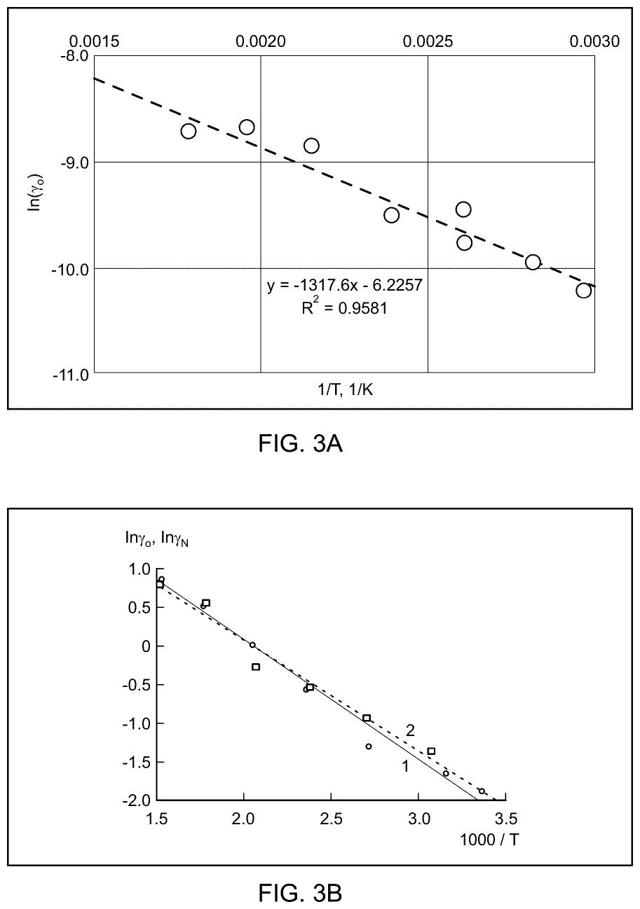

FIGS. 3A-3B show plots of ln(γ) versus 1/T for the heterogeneous recombination of oxygen atoms on quartz, under different conditions. Heterogeneous recombination probability, Y, is also a function of the composition of the surface and surface roughness. At a fixed temperature, pressure and gas composition γ can vary by five or more orders of magnitude depending on surface composition for quartz, β-cristobalite, Ti contaminated oxidized silicon (Ti—SiOx), Al2O3, Pt—TiO2, Al, stainless steel and Cu.

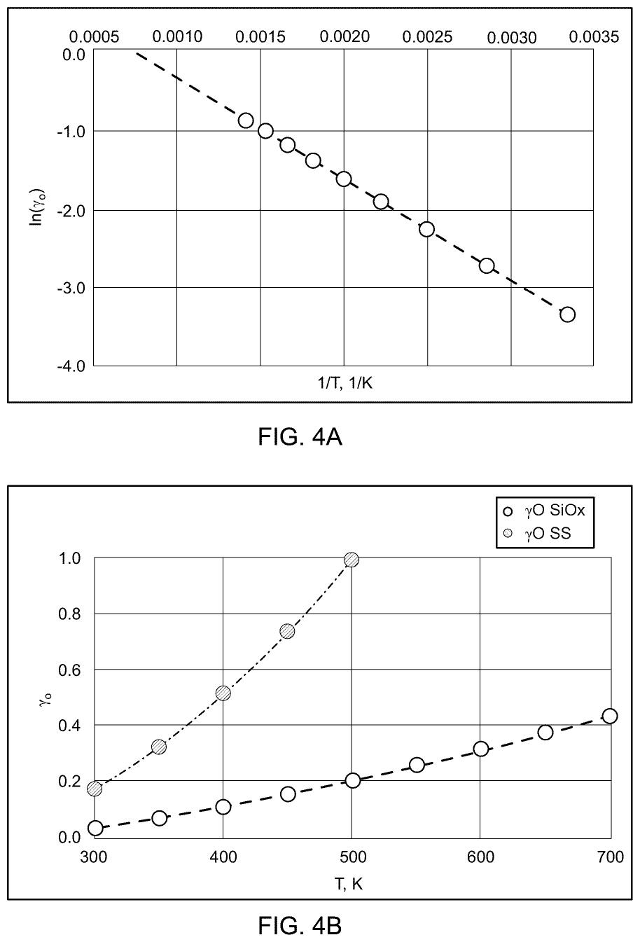

FIGS. 4A-4B show the increase in γ with increase in temperature for Ti—SiOx and stainless steel. In one non-limiting example, for Ti—SiOx at 700K (427° C.), γ is 0.42 so most radicals experiencing between 2 and 3 wall collisions will recombine to form O2(g) and not be available the etch EUV PR or other carbonaceous materials, while radicals experiencing zero or one wall collision will be transmitted through the channel and emerge with angular distribution of 0±5.7° for a 10:1 aspect ratio channel. For stainless steel γ varies between 0.17 and 1.0 for wall temperatures between room temperature and 227° C., so the transmitted radical angular distribution may be modulated by changing the wall temperature.

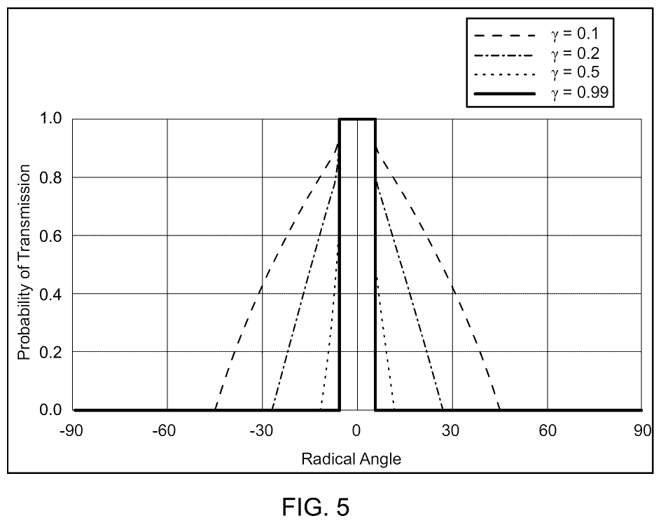

FIG. 5 shows the probability for a radical to be transmitted through a 20 mm×2 mm cylindrical channel as a function of initial elevation angle and γ.

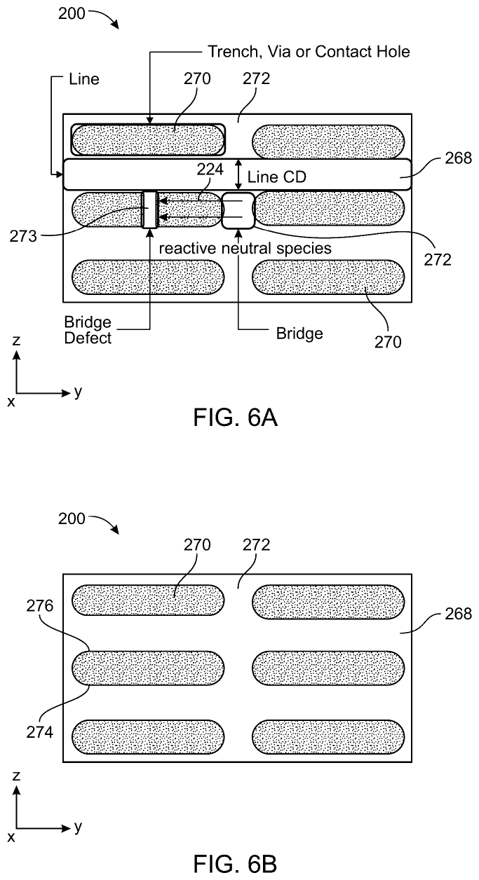

FIGS. 6A and 6B depict an example structure 200 including a series of lines 268 in between a plurality of trenches or openings 270. Although non-limiting, structure 200 may include a EUV photoresist, wherein bridges 272 are present between adjacent ends of the openings 270. A distance between sidewalls of adjacent openings 270 represents the line critical dimension (CD). In this example, one of the openings 270 may have a bridge defect 273 extending between opposite sidewalls 274, 276. To remove the bridge defect 273 without damaging or modifying other areas of the structure 200, a directed, angled beam of oxygen radicals 224 may be directed into a sidewall of the bridge defect 273, as shown in FIG. 6A. Using the channels 122 of the extraction plate 120 described herein, angular distribution (emittance) of the angled beam of oxygen radicals 224 is minimized/constrained. As a result, as shown in FIG. 6B, the bridge defect 273 is removed with no line CD loss (e.g., in the z-direction) and no bridge 272 loss (e.g., in the y-direction). FIG. 6B represents one possible implementation of the embodiments of the present disclosure, namely, to generate a beam of neutral species, including reactive neutral species like O, H, F, Cl, etc., directed toward a workpiece at a specified angle and angular distribution. Embodiments herein achieve neutral species angle control with a recombination channel array that quenches or deactivates reactive neutral species having trajectories outside of the specified angle range.

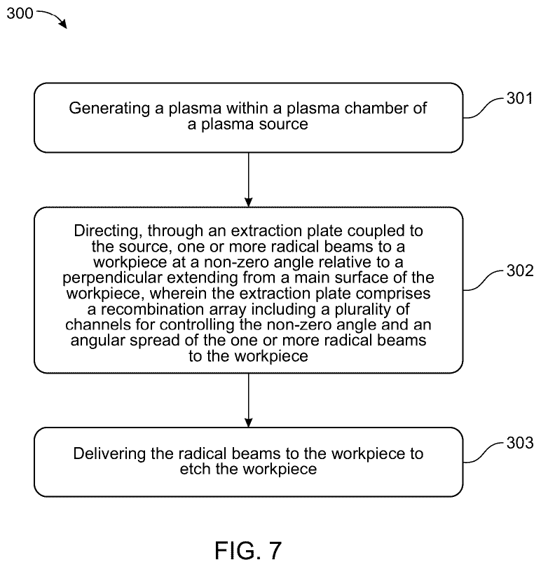

Turning to FIG. 7, a method 300 according to embodiments of the disclosure will be described. At block 301, the method 300 may include generating a plasma within a plasma chamber of a plasma source. At block 302, the method 300 may include directing, through an extraction plate coupled to the source, one or more radical beams to a workpiece at a non-zero angle relative to a perpendicular extending from a main surface of the workpiece, wherein the extraction plate comprises a recombination array including a plurality of channels for controlling the non-zero angle and an angular spread of the one or more radical beams to the workpiece.

In some embodiments, the method 300 may further include heating the recombination array, for example, to a temperature greater than 200° C. In some embodiments, the recombination array is maintained at a higher temperature than the chamber housing. In some embodiments, the method 300 may further include orientating the recombination array at the non-zero angle, wherein the one or more radical beams include oxygen radicals. The non-zero angle may be between 20° and 80°, depending on the workpiece 3D structure. In some embodiments, the channels of the recombination array may have a length and a width (e.g., diameter of inner cylinder), wherein a ratio of length to diameter is greater than 5:1, preferably 10:1. In some embodiments, the recombination array is made (in whole or part) from quartz, stainless steel, or aluminum.

At optional block 303, the method 300 may further include delivering the one or more radical beams to the workpiece to etch the workpiece. For example, the workpiece may include a 3D IC having one or more defects in a EUV photoresist layer. The angled radical beams may be used to more effectively correct the defects.

In sum, embodiments herein provide an apparatus and method to direct a highly focused beam of radicals, at a specified angle with low angle spread, at a workpiece like a 3D semiconductor integrated circuit. Although examples described herein relate to an angled beam of oxygen radicals, directed at a 3D patterned layer of EUV PR, it will be appreciated that the approaches of the disclosure apply to virtually any reactive neutral gas phase species including, but not limited to, H, N, O, F, CI, CF, CF2, CF3 and fluoroalkane radicals. It will be further appreciated that the approaches of the disclosure may apply to any substrate or layer that may be etched by these radicals, including but not limited to, EUV PR, SOH, CHM, SiO2, SION, Si3N4 and SiC.

Embodiments described herein may have many advantages. Directed reactive ion etching may be more effective and efficient when both ions and reactive neutrals contact the surface to be etched. The extraction angle of reactive neutrals may be precisely controlled through the use of neutral species channels in a manner that may not be possible using conventional techniques. This precise extraction angle control allows etching of densely packed features. In fact, in certain embodiments, the time to etch the sidewall of a trench may be reduced by an order of magnitude or more by being able to precisely direct the reactive neutrals to the desired locations.

Furthermore, unlike traditional RIE processes, embodiments of the present disclosure use a purely chemical process, with thermal radicals (e.g., oxygen atoms) having energy around 0.05 eV for which there is no sputtering, high (100:1) etch selectivity and no equipment damage.

Still furthermore, embodiments of the disclosure offer a great deal of value because the angled extraction plate is compatible with some existing plasma source and process chamber enabling tools currently available in the 1D patterning and EUVL descum market. High beam angles (e.g., >) 45°, which are desirable for 1D patterning and EUVL descum, may be achieved through channel design, material selection and temperature control, as described herein. Furthermore, since halides and fluoroalkanes are not required, for the case of EUV PR patterning, this configuration will have significantly lower bill of materials (BOM) cost since there is no need for etch resistant materials and there is no need for pulsed DC wafer bias, further eliminating more BOM cost.

The foregoing discussion has been presented for purposes of illustration and description and is not intended to limit the disclosure to the form or forms disclosed herein. For example, various features of the disclosure may be grouped together in one or more aspects, embodiments, or configurations for the purpose of streamlining the disclosure. However, it should be understood that various features of the certain aspects, embodiments, or configurations of the disclosure may be combined in alternate aspects, embodiments, or configurations. Moreover, the following claims are hereby incorporated into this Detailed Description by this reference, with each claim standing on its own as a separate embodiment of the present disclosure.

As used herein, an element or step recited in the singular and proceeded with the word “a” or “an” should be understood as not excluding plural elements or steps, unless such exclusion is explicitly recited. Furthermore, references to “one embodiment” of the present disclosure are not intended to be interpreted as excluding the existence of additional embodiments that also incorporate the recited features.

The use of “including,” “comprising,” or “having” and variations thereof herein is meant to encompass the items listed thereafter and equivalents thereof as well as additional items. Accordingly, the terms “including,” “comprising,” or “having” and variations thereof are open-ended expressions and can be used interchangeably herein.

All directional references (e.g., proximal, distal, upper, lower, upward, downward, left, right, lateral, longitudinal, front, back, top, bottom, above, below, vertical, horizontal, radial, axial, clockwise, and counterclockwise) are only used for identification purposes to aid the reader's understanding of the present disclosure, and do not create limitations, particularly as to the position, orientation, or use of this disclosure. Connection references (e.g., attached, coupled, connected, and joined) are to be construed broadly and may include intermediate members between a collection of elements and relative movement between elements unless otherwise indicated. As such, connection references do not necessarily infer that two elements are directly connected and in fixed relation to each other.

Furthermore, identification references (e.g., primary, secondary, first, second, third, fourth, etc.) are not intended to connote importance or priority, but are used to distinguish one feature from another. The drawings are for purposes of illustration only and the dimensions, positions, order and relative sizes reflected in the drawings attached hereto may vary.

Still furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

While certain embodiments of the disclosure have been described herein, the disclosure is not limited thereto, as the disclosure is as broad in scope as the art will allow and the specification may be read likewise. Therefore, the above description are not to be construed as limiting. Those skilled in the art will envision other modifications within the scope and spirit of the claims appended hereto.

What is claimed is:

1. A workpiece processing apparatus, comprising:
a plasma source operable to generate a plasma within a plasma chamber enclosed by a chamber housing; and
an extraction plate coupled to the chamber housing, wherein the extraction plate comprises a recombination array including a plurality of channels operable to direct one or more radical beams to a workpiece, and wherein the extraction plate is oriented at a non-zero angle relative to a perpendicular extending from a main surface of the workpiece.

2. The workpiece processing apparatus of claim 1, wherein the recombination array is maintained at a higher temperature than the chamber housing.

3. The workpiece processing apparatus of claim 2, wherein the higher temperature is greater than 200° C.

4. The workpiece processing apparatus of claim 1, further comprising a first radiation shield positioned between the recombination array and the workpiece.

5. The workpiece processing apparatus of claim 4, further comprising a second radiation shield within the plasma chamber.

6. The workpiece processing apparatus of claim 1, wherein the recombination array is oriented at the non-zero angle relative to the perpendicular extending from the main surface of the workpiece.

7. The workpiece processing apparatus of claim 6, wherein the non-zero angle is approximately 45°.

8. The workpiece processing apparatus of claim 1, wherein each channel of the plurality of channels has a length and a diameter, and wherein the length is at least five times greater than the diameter.

9. The workpiece processing apparatus of claim 1, wherein each channel of the plurality of channels is defined by an inner surface, and wherein quartz is provided along the inner surface.

10. The workpiece processing apparatus of claim 1, wherein the recombination array is made from quartz, stainless steel, or aluminum.

11. The workpiece processing apparatus of claim 1, wherein the one or more radical beams include oxygen radicals.

12. A workpiece processing apparatus, comprising:
a plasma source operable to generate a plasma within a plasma chamber enclosed by a chamber housing; and
an extraction plate forming a portion of the chamber housing, wherein the extraction plate comprises a recombination array including a plurality of channels operable to direct one or more radical beams to a workpiece, and wherein the extraction plate is oriented at a non-zero angle relative to a perpendicular extending from a main surface of the workpiece.

13. The workpiece processing apparatus of claim 12, wherein the recombination array is maintained at a higher temperature than the chamber housing.

14. The workpiece processing apparatus of claim 13, wherein the higher temperature is greater than 200° C.

15. The workpiece processing apparatus of claim 12, further comprising a first radiation shield positioned between the recombination array and the workpiece.

16. The workpiece processing apparatus of claim 15, further comprising a second radiation shield within the plasma chamber.

17. The workpiece processing apparatus of claim 12, wherein the recombination array is oriented at the non-zero angle relative to the perpendicular extending from the main surface of the workpiece.

18. The workpiece processing apparatus of claim 17, wherein the non-zero angle is approximately 45°.

19. The workpiece processing apparatus of claim 12, wherein each channel of the plurality of channels has a length and a diameter, and wherein the length is at least five times greater than the diameter.

20. The workpiece processing apparatus of claim 12, wherein the recombination array is made from quartz, stainless steel, or aluminum.
